(19) United States
(12) Patent Application Publication
(10) Pub. No.: US 2023/0259033 A1
(43) Pub. Date: Aug. 17, 2023

(54) Semiconductor Device and Method of Applying a Single Liquid Photoresist Material to Semiconductor Wafer

(71) Applicant: STATS ChipPAC Pte. Ltd., Singapore (SG)

(72) Inventors: Giwoong Nam, Incheon (KR); Junghwan Jang, Incheon (KR); Inhee Hwang, Chungcheongnam-do (KR)

(73) Assignee: STATS ChipPAC Pte. Ltd., Singapore (SG)

(21) Appl. No.: 17/650,709

(22) Filed: Feb. 11, 2022

(51) Int. Cl. G03F 7/16; H01L 21/027

(52) U.S. Cl. CPC G03F 7/162; H01L 21/027

(57) ABSTRACT

A semiconductor manufacturing device has an outer cup and inner cup with a wafer mount disposed within the outer cup. A semiconductor wafer is disposed on the wafer mount. A dispenser dispenses a photoresist material onto a surface of the semiconductor wafer. A controller controls the dispenser to apply in a single application, the photoresist material to the surface of the semiconductor wafer while rotating at a first speed to form a thickness of the photoresist material up to 12.0 micrometers, or in the range of 3.0 to 12.0 micrometers. The first speed ranges from 400 to 700 RPM. The controller controls the dispenser to discontinue application of the photoresist material while rotating the semiconductor wafer at the first speed. The photoresist material dries while rotating the semiconductor wafer. The controller controls the dispenser to apply a coating to the semiconductor wafer prior to applying the photoresist material.

### FIELD OF THE INVENTION

The present invention relates in general to semiconductor devices and, more particularly, to a semiconductor device and method of applying a single liquid photoresist material to a semiconductor wafer while the semiconductor wafer is rotating.

### BACKGROUND OF THE INVENTION

Semiconductor devices are commonly found in modern electronic products. Semiconductor devices perform a wide range of functions, such as signal processing, high-speed calculations, transmitting and receiving electromagnetic signals, controlling electronic devices, photo-electric, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Semiconductor devices contain active and/or passive type electrical components. The electrical interconnection of the active and passive electrical components requires formation of electrical interconnect structures, such as trace lines, redistribution lines (RDL), and external contact pads. The formation of active and passive electrical components, as well as the electrical interconnect structures, utilizes a photolithographic process which requires certain areas of the semiconductor wafer to be masked off to perform the semiconductor manufacturing operation, e.g., implantation step or applying conductive material, in the desired area.

FIG. 1a illustrates semiconductor wafer 50 containing semiconductor devices. In FIG. 1b, photoresist 52 is applied to active surface 54 of semiconductor wafer 50. In FIG. 1c, mask 56 is disposed over photoresist 52. Mask 56 is a pattern that exposes or isolates areas of semiconductor wafer 50 for the semiconductor manufacturing operations. An ultra-violet (UV) light 58 is illuminated over mask 56 and exposed areas of photoresist 52. In areas 60 covered by mask 56, UV light 58 is blocked from photoresist 52. In opening 66 of mask 56, photoresist 52 is exposed to UV light 58. Mask 56 is removed. Photoresist 52 can be positive or negative in reaction. In the case of positive photoresist, area 68b of photoresist 52 is degraded by UV light 58, while area 68a is unaffected by the UV light. A developer or solvent is applied to remove areas 68b, while leaving areas 68a, as shown in FIG. 1d. Removing area 68b of photoresist 52 exposes surface 70 of semiconductor wafer 50 to semiconductor manufacturing processes, while isolating the remainder of surface 54 of the semiconductor wafer. In the case of negative photoresist, area 68b of photoresist 52 is cured or hardened by UV light 58, while area 68a remains soluble. A developer or solvent is applied to remove areas 68a, while leaving areas 68b, as shown in FIG. 1e. Removing area 68a of photoresist 52 exposes surface 72 of semiconductor wafer 50 to semiconductor manufacturing processes, while isolating the remainder of surface 54 of the semiconductor wafer.

A common design goal for a semiconductor device is to reduce the package size and profile, while gaining in functionality. The semiconductor devices need to accommodate a higher density of components in a smaller area. The demand for more input/output (I/O) and decreasing semiconductor package size requires a smaller RDL line spacing. In forming the RDL, liquid photoresist (LPR) thickness may range from 3.0-10.0 μm. For larger wafers, e.g., 300 or more millimeters (mm) in diameter, the thicker the LPR, the wider the line spacing. A wider line spacing is counter to the goal of higher density I/O. In addition, two LPR materials are often used depending on the LPR thickness or line spacing pattern size in 300+ mm wafer process, which increases manufacturing steps and cost.

### BRIEF DESCRIPTION OF THE DRAWINGS

FIGS. 1a-1e illustrate a known photolithographic process using photoresist material;

FIGS. 2a-2p illustrate a process of applying a single liquid photoresist material to a semiconductor wafer; and

FIGS. 3a-3c illustrate a semiconductor wafer with a plurality of semiconductor die separated by a saw street.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are mounted to a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

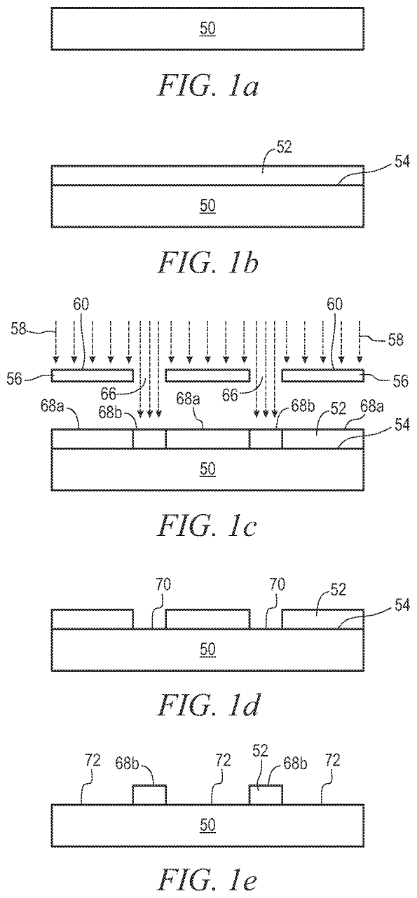

The electrical interconnection of the active and passive electrical components requires formation of electrical interconnect structures, such as trace lines, RDL, and external contact pads. The formation of active and passive electrical components, as well as the electrical interconnect structures, utilizes a photolithographic process which requires certain areas of the semiconductor wafer to be masked off using a photoresist material to perform the semiconductor manufacturing operation in the desired area, as described in FIGS. 1a-1e in the background.

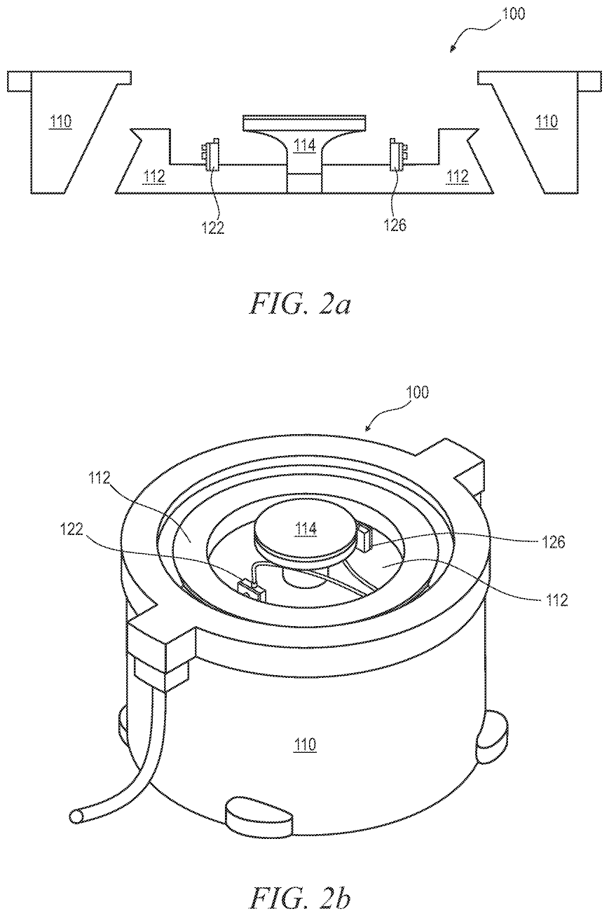

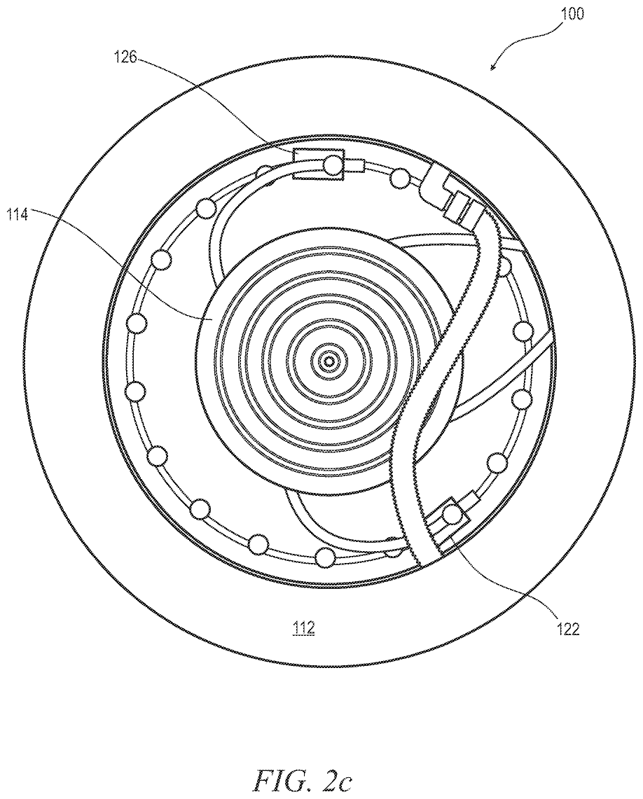

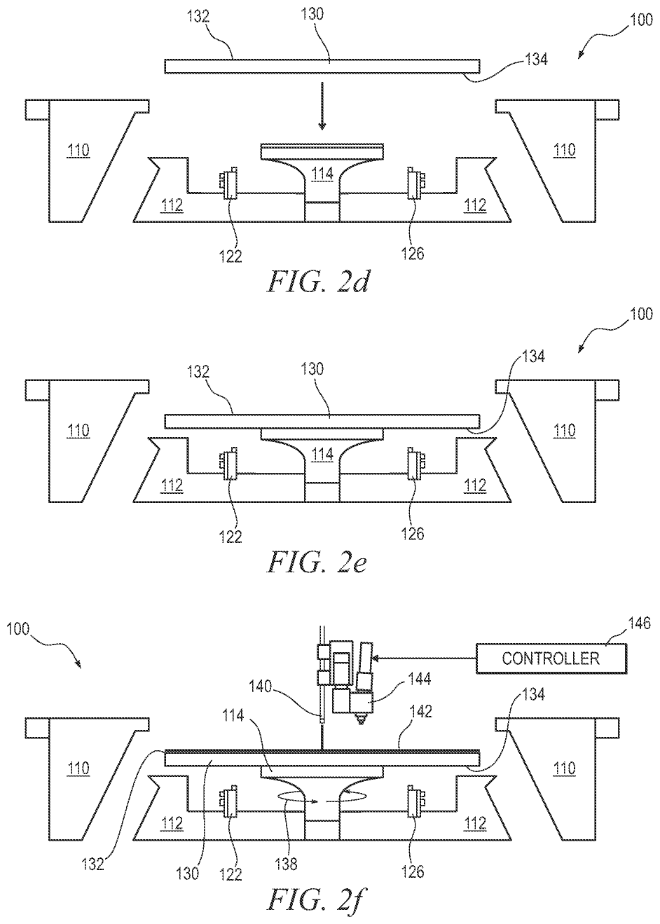

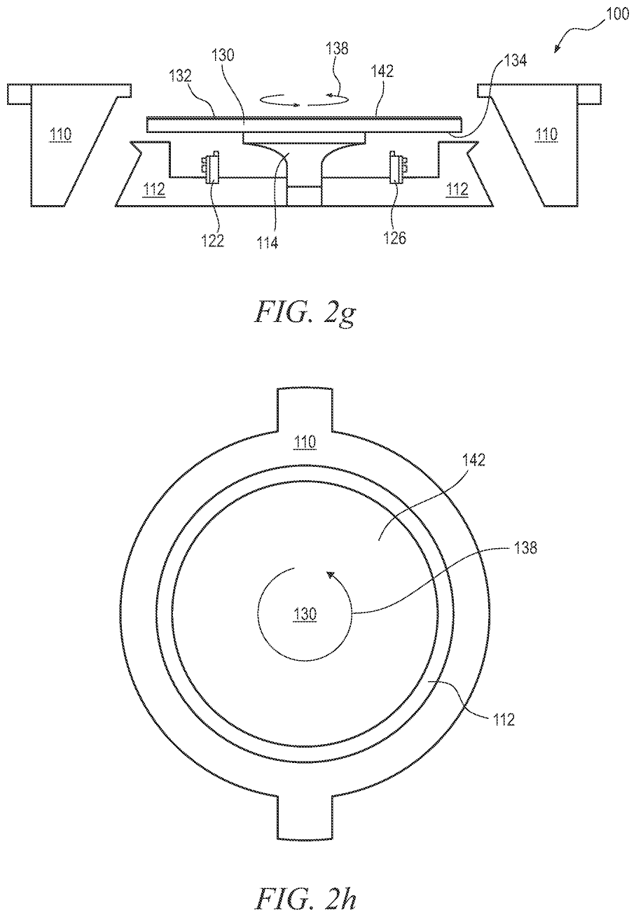

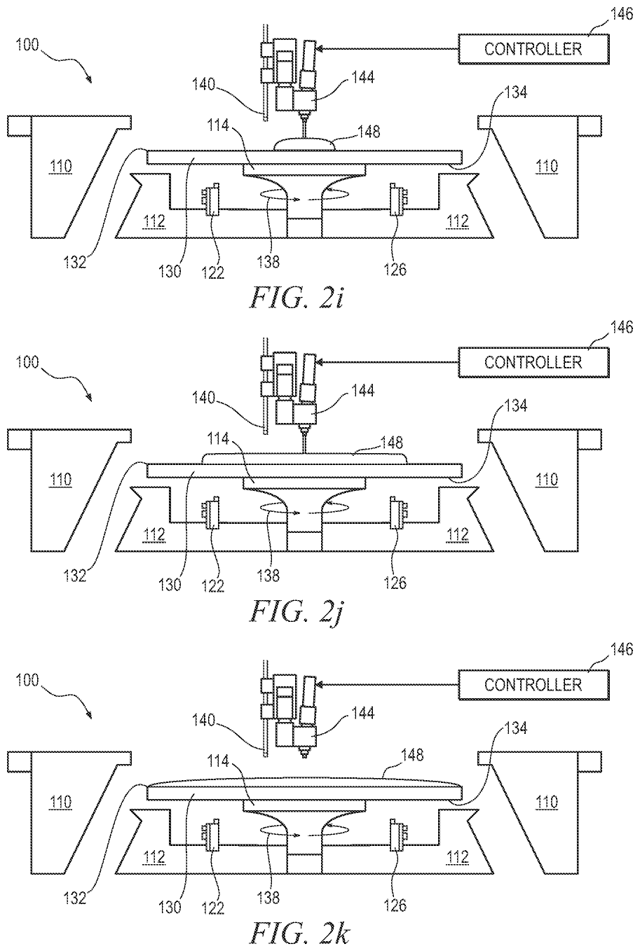

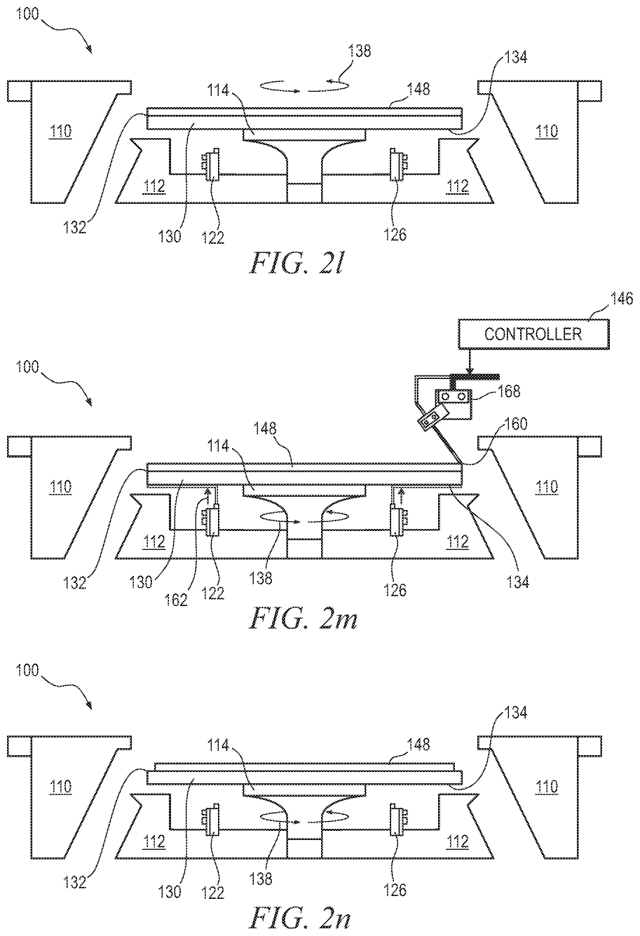

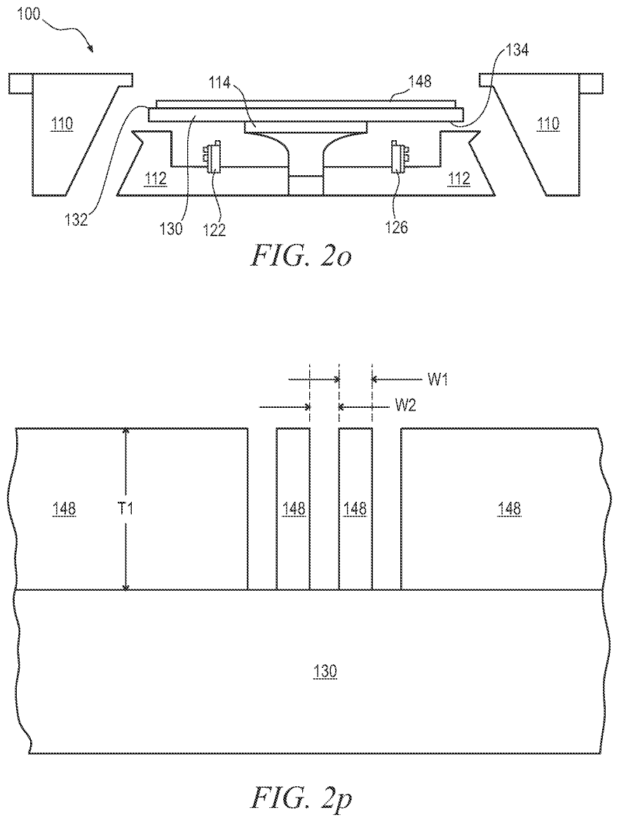

FIGS. 2a-2p illustrate a process of applying a single liquid photoresist material to a semiconductor wafer while the semiconductor wafer continues to rotate. FIG. 2a shows a cross-sectional view of semiconductor manufacturing equipment 100 for applying materials, such as photoresist, to the active surface of a semiconductor wafer. Semiconductor manufacturing equipment 100 includes outer cup 110 and inner cup 112 with wafer suction mount 114. Ports or nozzles 122 and 126 provide for wafer backside rinse. FIG. 2b is a perspective view of semiconductor manufacturing equipment 100 with outer cup 110, inner cup 112, and wafer suction mount 114. FIG. 2c illustrates further detail of wafer suction mount 114, and ports 122 and 126 for wafer backside rinse.

In FIG. 2d, semiconductor wafer 130 is positioned over wafer suction mount 114 with active surface 132 oriented away from the wafer suction mount and backside surface 134 oriented toward the wafer suction mount. FIG. 2e shows semiconductor wafer 130 in contact with wafer suction mount 114. Wafer suction mount 114 draws a vacuum to apply negative pressure to backside surface 134 of semiconductor wafer 130 to hold the semiconductor wafer in place during the operations described for FIGS. 2f-2p.

In FIG. 2f, wafer suction mount 114 rotates in the direction of arrow 138 at a speed of 50-100 revolutions per minute (RPM). Port or nozzle 140 applies a coating 142 of propylene glycol monomethyl ether acetate (PGMEA), propylene glycol monomethyl ether (PGME), ethylene glycol monomethyl ether acetate (EGMEA), or mixed solution of PGMEA and PGME as a pre-wet step to reduce resist consumption (RRC) and minimize coating defects, such as bubbles. Port or nozzle 144 dispenses liquid photoresist material or LRP in a later step. The pre-wet step of PGMEA enhances wetting of the later applied LPR. In FIG. 2g, wafer suction mount 114 continues to rotate semiconductor wafer 130 in the direction of arrow 138 at less than 100 RPM to dry coating 142 partially. FIG. 2h is a top view of semiconductor wafer 130 rotating on wafer suction mount 114 to perform at least partially drying step for coating 142. The partially dry coating 142 reduces resistance between active surface 132 of semiconductor wafer 130 and LPR.

In FIG. 2i, controller 146 controls port 144 to dispense a light sensitive material reactive to light onto active surface 132 of semiconductor wafer 130 while the wafer is rotating. In one embodiment, port 144 dispenses liquid photoresist material 148 having a viscosity of 84 cp onto active surface 132 of semiconductor wafer 130 while the wafer is rotating. In particular, LPR 148 is dispensed with high speed revolutions of wafer suction mount 114, e.g., at a rotation speed of at least 400 revolutions per minute (RPM). The LPR rotational speed while dispensing LPR 148 may be between 400-700 RPM. FIG. 2j shows controller 146 controlling port 144 to continue the application of the same LPR 148 onto active surface 132 while wafer suction mount 114 rotates semiconductor wafer 130 at the LPR rotation speed. The application of photoresist material 148 while wafer suction mount 114 rotates in the direction of arrow 138 produces a flat surface for the photoresist material. FIG. 2k shows controller 146 controlling port 144 to shut-off and discontinue the application of LPR 148 onto active surface 132 while wafer suction mount 114 continues to rotate semiconductor wafer 130 at the LPR rotation speed. In FIG. 2l, wafer suction mount 114 continues to rotate in the direction of arrow 138 to dry LPR 148 and maintain the layer's thickness. FIGS. 2i-21 illustrate a single manufacturing step of dispensing a single LPR material 148 onto active surface 132, as wafer suction mount 114 rotates semiconductor wafer 130 at the LPR rotation speed. The application of the single LPR material 148, as described above, allows the thickness of the LPR material to be controlled to a range of 3.0-12.0 μm, or up to 12.0 μm, for a 300+ mm wafer.

In FIG. 2m, wafer suction mount 114 continues to rotate semiconductor wafer 130 at a main speed to evenly distribute LRP 148. The main speed of semiconductor wafer 130 is 50-2600 RPM to control the thickness and uniformity of photoresist material 148 over active surface 132. Ports 122 and 126 dispense solution, such as PGMEA, PGME, EGMEA, or mixed solution of PMGEA and PGME, with arrow 162 for wafer backside rinse. Photoresist material 148 is dried to perform an edge bead removal (EBR) region 160, which involves removal of beaded photoresist material from the edge of semiconductor wafer 130 formed during coating of the photoresist material on the semiconductor wafer. Controller 146 controls port or nozzle 168 to dispense a solvent to remove EBR region 160.

In FIG. 2n, wafer suction mount 114 continues to rotate semiconductor wafer 130 at 200 RPM to completely dry. FIG. 2o shows semiconductor wafer 130 with a coating of photoresist material 148 and EBR region 160 removed. Maintaining rotational speed during a single step of dispensing LPR provides for control of LPR thickness. FIG. 2p shows LPR 148 deposited on semiconductor wafer 130 and having thickness T1 in the range of 3.0-12.0 μm, or up to 12.0 μm, for a 300+ mm wafer. When patterning LPR 148 in a photolithographic process, as described in FIGS. 1a-1e, line spacing width W1 can be 1.0 μm and W2 can be 1.0 μm with T1 of 3.0 μm. Alternatively, line spacing width W1 can be 1.8 μm and W2 can be 1.8 μm with T1 of 10.0 μm.

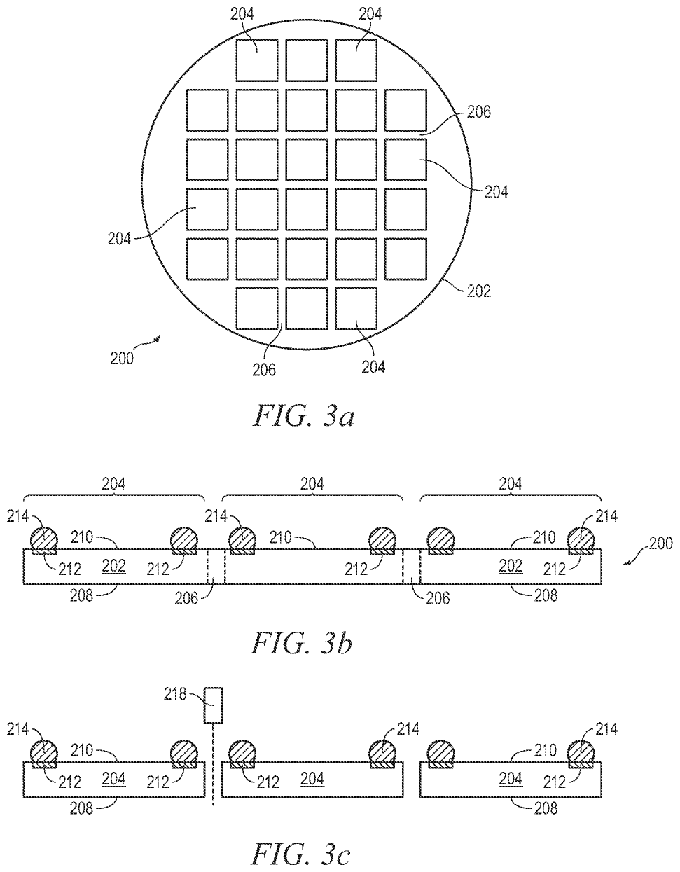

FIG. 3a shows a semiconductor wafer 200 with a base substrate material 202, such as silicon, germanium, aluminum phosphide, aluminum arsenide, gallium arsenide, gallium nitride, indium phosphide, silicon carbide, or other bulk material for structural support. A plurality of semiconductor die or components 204 is formed on wafer 200 separated by a non-active, inter-die wafer area or saw street 206. Saw street 206 provides cutting areas to singulate semiconductor wafer 200 into individual semiconductor die 204. In one embodiment, semiconductor wafer 200 has a width or diameter of 100-450 mm.

FIG. 3b shows a cross-sectional view of a portion of semiconductor wafer 200. Each semiconductor die 204 has a back or non-active surface 208 and an active surface 210 containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active surface 210 to implement analog circuits or digital circuits, such as digital signal processor (DSP), application specific integrated circuits (ASIC), memory, or other signal processing circuit. Semiconductor die 204 may also contain IPDs, such as inductors, capacitors, and resistors, for RF signal processing.

An electrically conductive layer 212 is formed over active surface 210 using PVD, CVD, electrolytic plating, electroless plating process, or other suitable metal deposition process. Conductive layer 212 can be one or more layers of aluminum (Al), copper (Cu), tin (Sn), nickel (Ni), gold (Au), silver (Ag), or other suitable electrically conductive material. Conductive layer 212 operates as contact pads electrically connected to the circuits on active surface 210.

An electrically conductive bump material is deposited over conductive layer 212 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 212 using a suitable attachment or bonding process. In one embodiment, the bump material is reflowed by heating the material above its melting point to form balls or bumps 214. In one embodiment, bump 214 is formed over an under bump metallization (UBM) having a wetting layer, barrier layer, and adhesive layer. Bump 214 can also be compression bonded or thermocompression bonded to conductive layer 212. Bump 214 represents one type of interconnect structure that can be formed over conductive layer 212. The interconnect structure can also use bond wires, conductive paste, stud bump, micro bump, or other electrical interconnect.

In FIG. 3c, semiconductor wafer 200 is singulated through saw street 206 using a saw blade or laser cutting tool 218 into individual semiconductor die 204. The individual semiconductor die 204 can be inspected and electrically tested for identification of KGD post singulation.

While one or more embodiments of the present invention have been illustrated in detail, the skilled artisan will appreciate that modifications and adaptations to those embodiments may be made without departing from the scope of the present invention as set forth in the following claims.

What is claimed:

1. A method of making a semiconductor device, comprising:
providing a semiconductor wafer; and
applying in a single application, a photoresist material to a surface of the semiconductor wafer while rotating at a first speed to form a thickness of the photoresist material up to 12.0 micrometers.

2. The method of claim 1, wherein the thickness of the photoresist material ranges from 3.0 to 12.0 micrometers.

3. The method of claim 1, wherein the first speed ranges from 400 to 700 revolutions per minute.

4. The method of claim 1, further including discontinuing application of the photoresist material while rotating the semiconductor wafer at the first speed.

5. The method of claim 1, further including drying the photoresist material while rotating the semiconductor wafer.

6. The method of claim 1, further including rotating the semiconductor wafer at a second speed after applying the photoresist material.

7. A method of making a semiconductor device, comprising applying in a single application, a photoresist material to a surface of a semiconductor wafer while rotating at a first speed to form a thickness of the photoresist material in the range of 3.0 to 12.0 micrometers.

8. The method of claim 7, wherein the first speed ranges from 400 to 700 revolutions per minute.

9. The method of claim 7, further including discontinuing application of the photoresist material while rotating the semiconductor wafer at the first speed.

10. The method of claim 7, further including drying the photoresist material while rotating the semiconductor wafer.

11. The method of claim 7, further including rotating the semiconductor wafer at a second speed after applying the photoresist material.

12. The method of claim 7, further including applying a coating to the surface of the semiconductor wafer prior to applying the photoresist material.

13. The method of claim 7, further including providing a controller to control the application of the photoresist material.

14. A semiconductor manufacturing device, comprising:
a wafer mount;
a semiconductor wafer disposed on the wafer mount;
a dispenser for dispensing a photoresist material onto a surface of the semiconductor wafer; and
a controller for controlling the dispenser to apply in a single application, the photoresist material to the surface of the semiconductor wafer while rotating at a first speed to form a thickness of the photoresist material up to 12.0 micrometers.

15. The method of claim 14, wherein the thickness of the photoresist material ranges from 3.0 to 12.0 micrometers.

16. The semiconductor manufacturing device of claim 14, wherein the first speed ranges from 400 to 700 revolutions per minute.

17. The semiconductor manufacturing device of claim 14, wherein the controller controls the dispenser to discontinue application of the photoresist material while rotating the semiconductor wafer at the first speed.

18. The semiconductor manufacturing device of claim 14, wherein the photoresist material dries while rotating the semiconductor wafer.

19. The semiconductor manufacturing device of claim 14, wherein the semiconductor wafer rotates at a second speed.

20. A semiconductor device, comprising
a wafer mount;
a semiconductor wafer disposed on the wafer mount;
a dispenser for dispensing a photoresist material onto a surface of the semiconductor wafer; and
a controller for controlling the dispenser to apply in a single application, the photoresist material to the surface of the semiconductor wafer while rotating at a first speed to form a thickness of the photoresist material in the range of 3.0 to 12.0 micrometers.

21. The semiconductor manufacturing device of claim 20, wherein the first speed ranges from 400 to 700 revolutions per minute.

22. The semiconductor manufacturing device of claim 20, wherein the controller controls the dispenser to discontinue application of the photoresist material while rotating the semiconductor wafer at the first speed.

23. The semiconductor manufacturing device of claim 20, wherein the photoresist material dries while rotating the semiconductor wafer.

24. The semiconductor manufacturing device of claim 20, wherein the semiconductor wafer rotates at a second speed.

25. The semiconductor manufacturing device of claim 20, wherein the controller controls the dispenser to apply a coating to the surface of the semiconductor wafer.
